(19) United States
(12) Patent Application Publication
(10) Pub. No.: US 2026/0150697 A1
(43) Pub. Date: May 28, 2026

(54) SEMICONDCUTOR DEVICE AND SEMICONDCUTOR MODULE ARRANGEMENT

(71) Applicant: Infineon Technologies AG, Neubiberg (DE)

(72) Inventors: Christian MÜLLER, Schweinfurt (DE); Daniel DOMES, Werl (DE)

(21) Appl. No.: 19/398,578

(22) Filed: Nov. 24, 2025

(30) Foreign Application Priority Data
Nov. 22, 2024 (DE) 102024134423.7

(51) Int. Cl. H10W 42/20; H05K 1/02; H05K 1/16; H10W 70/60; H10W 70/65

(52) U.S. Cl. CPC H10W 42/20; H05K 1/0218; H05K 1/162; H10W 70/611; H10W 70/65; H05K 2201/0723

(57) ABSTRACT

A semiconductor device may comprise an insulator substrate, a second substrate, a first structured metallization layer comprising a first section configured to operate at a first potential, and a second section configured to operate at a second potential. The insulator substrate may comprise a second structured metallization layer which may comprise a first section coupled to the first potential and a second section coupled to the second potential. At least one routable third structured metallization layer may comprise a first segment coupled to the second potential and a second segment coupled to the first potential.

### RELATED APPLICATION

This application claims priority to German Patent Application No. 102024134423.7, filed on November 22, 2024, entitled “SEMICONDCUTOR DEVICE AND SEMICONDCUTOR MODULE ARRANGEMENT”, which is incorporated by reference herein in its entirety.

### TECHNICAL FIELD

The present disclosure relates to a low EMI semiconductor device comprising an insulator substrate, a second substrate, arranged at a first surface of the insulator substrate; a first structured metallization layer arranged at a second surface of the insulator substrate opposite the first surface, the first structured metallization layer comprising a first section configured to operate at a first potential, and a second section configured to operate at a second potential, wherein the insulator substrate comprises a second structured metallization layer buried in the insulator substrate configured for EMI shielding, arranged adjacent to the second substrate.

### BACKGROUND

In today’s power modules, low inductive and symmetric designs are targeted and, especially with focus on fast switching devices, are essential for operation. Within this framework, the main motivation for low inductive and symmetric designs is a reduction of overvoltage and enabling of very steep di/dt and dv/dt mainly by using a low inductive design, a reduction of inter chip oscillations during operation mainly by using symmetric designs and minimizing parasitic effects, and a reduction of electromagnetic interference (EMI) mainly by using symmetric designs.

For low inductive and symmetric designs, many attempts have been made to effectively reduce parasitic effects.

With respect to EMI, it is known e.g. from DE 102013210146 A1, that electrically connected metal plates placed between a first plane and a second plane of a substrate, can have a positive influence on (conducted) EMI. In this setup, the first plane is used for placing power semiconductor devices, their connecting structures, and layout components. The second plane is typically connected to heatsink and, hence, to the electrical potential of the heatsink which is ground typically.

As per DE 102013210146 A1, in case of a half bridge module, EMI wise these inner shielding structures are most efficient, if they are designed in a way, that the first element of the electrically connected metal plates has the same coupling capacitance as the second element of the electrically connected metal plates against the above mentioned second plane of the substrate.

Between the first substrate plane and the inner shielding elements of the third plane, electrical connections can be established to ensure the correct electrical potentials of the inner elements coupling electrically against the second plane.

For effective EMI reduction, the first element of the electrically connected metal plates may be connected to the positive potential of a DC link voltage (DC+) and the second element of electrically connected metal plates may be connected to the negative potential of the DC link voltage (DC-).

However, it is also desirable to implement a snubber capacitor functionality. This is usually done by installing Surface Mount Devices (SMD), e.g. external capacitors, at a top- or bottom side of a substrate of a power module. A common disadvantage of SMDs is however that area which is needed for mounting semiconductor devices is consumed, local heat is generated and the SMDs interact with neighboring components, e.g. with a potting get or with semiconductors.

It is therefore desirable to overcome the above-mentioned deficiencies.

### SUMMARY

According to a first aspect of the present disclosure, a semiconductor device of the aforementioned kind is provided, wherein the second structured metallization layer comprises a first section, coupled to the first potential, a second section, coupled to the second potential, wherein the first section and the second section are non-overlapping. The insulator substrate further comprises at least one routable third structured metallization layer, comprising: a first segment coupled to the second potential and a second segment coupled to the first potential. The first section of the second structured metallization layer forms a first snubber capacitance with the first segment of the third structured metallization layer.

According to embodiments of the present disclosure, in an insulator substrate, which may separate the second substrate from the first metallization layer, passive elements are implemented to reduce electro-magnetic interference/emission and provide an additional snubber capacitor functionality on power module level without using layout area for (SMD like) passive components at, for example, the first metallization layer. To implement a basic snubber capacitance inside the insulator substrate, the first snubber capacitance is formed between the first section of the second metallization layer and a first segment of the third structured metallization layer with the material of the insulator substrate in between acting as a dielectric.

The first and the second section of the second metallization layer are non-overlapping and form a shielding capacitance together with the second substrate. The second substrate may be a metal substrate or in general a conductive substrate. The first and the second section of the second metallization layer may be spaced apart from the second substrate by material of the insulator substrate, wherein the material of the insulator substrate forms the dielectric for the shielding capacitance. The first segment of the third structured metallization layer may be arranged between the second metallization layer and the first metallization layer inside the insulator substrate. Thereby, the material of the insulator substrate forms the dielectric between the single layers of each of the second metallization layer and the first metallization layer. The first segment of the third structured metallization layer overlaps the first section of the second structured metallization layer and is spaced apart therefrom by the material of the insulator substrate, thus forming a first snubber capacitance.

It is to be noted, that the term “structured metallization layer” may be referred to as a layer having different sections/segments in more or less the same plane. The sections/segments may be separate from one another, linked to one another or galvanically isolated from one another. Different segments of the structured metallization layer may have different functionality.

In particular, the snubber capacitance is a DC snubber capacitance for reducing electro-magnetic interference and/or emission. A snubber capacitance may be a type of capacitor used in electrical circuits to reduce voltage spikes, ringing, and electromagnetic interference (EMI) caused by the switching of inductive loads, such as relays, solenoids, and motors, etc.

In an embodiment the second section of the second structured metallization layer forms a second snubber capacitance with the second segment of the third structured metallization layer. In this way, a second snubber capacitance is implemented, as the second section of the second structured metallization layer is spaced apart from the second segment of the third structure metallization layer by the material of the insulator substrate. Like the first snubber capacitance, the second snubber capacitance is formed inside the insulator substrate and arranged between the second metallization layer and the first metallization layer. Each capacitance of the first and second snubber capacitance may be connected to a corresponding switch.

In an embodiment the third structured metallization layer comprises a plurality of routable layers, the plurality of layers forming intermeshing layer structures alternatingly coupled to the first potential and to the second potential, thereby forming multiple stacked snubber capacitances within the insulator substrate. To form multiple stacked snubber capacitances, the third structured metallization layer may comprise a plurality of layers. To form snubber capacitances, the plurality of layers may be alternatingly coupled to the first and the second potential.

The single layers of the plurality of layers may be spaced apart from one another by the material of the insulator substrate which acts as a dielectric to form the respective snubber capacitances. The layer structures may be stacked and/or intermeshing, that is, at least in part overlapping. In contrast to the second metallization layer which comprises layers which are non-overlapping, the plurality of layers of the third metallization layer needs to be at least in part overlapping one another. By stacking a plurality of layers inside the insulator substrate, a stacked capacitor is created inside the insulator substrate. The capacitor may comprise layers which are stacked symmetrically inside the insulator substrate, and/or layers which are arranged asymmetrically inside the insulator substrate. Thereby it becomes possible to adapt the overall capacitance inside the insulator substrate to possible asymmetries in switching speed of semiconductor devices coupled to the snubber capacitances.

In particular, the plurality of intermeshing layer structures is embedded in the first insulator substrate and arranged between the first structured metallization layer and the second structured metallization layer.

Further, the intermeshing layer structures are alternatingly overlapping one another and form a plate capacitor structure within the first insulator substrate.

In an embodiment the insulator substrate is one of a multilayer ceramic substrate, a multilayer PCB, or a multi-layer resin-based substrate. The insulator substrate may be any suitable substrate which is made of an insulating material. According to embodiments of the present disclosure, multi-layer ceramics substrates which are integrated in a power-semiconductor module are used in a way that allows integrating/embedding passive elements inside/as functional part of the multi-layer ceramics substrate.

In comparison to common approaches that use the first structured metallization layer for attaching passive elements, e.g., by soldering SMD-like devices on a copper surface, the present disclosure offers several advantages, as will be detailed below:

Firstly, integration of passive elements in the inner/buried layers of the insulator substrate saves area at the first structured metallization layer that can be used for attaching/mounting power-semiconductor devices instead.

Secondly, heat generation of passive elements in the inner/buried layers is optimized in terms of that the heat is generated less locally than in an SMD-like device and is dissipated more efficiently due to the large thermal spreading. In other words, the insulator substrate may act as a heat spreader.

Thirdly, by embedding passive elements or the functionality of passive elements inside a multi-layer ceramics substrate, interaction of passive elements with other components, e.g., a potting gel and/or edge termination of power semiconductors, is minimized. Consequently, failures in reliability tests may be avoided or at least reduced.

Accordingly, in a further embodiment, the first section of the first structured metallization layer is configured to receive a first semiconductor die and the second section of the first structured metallization layer is configured to receive a second semiconductor die. The first metallization layer may also be a routing layer to which the first and the second semiconductor dies are attached, that is, at least electrically and/or thermally coupled. Both the first semiconductor die and the second semiconductor die may be an IBGT or Si/SiC-MOSFET or a JFET or a GaN-HEMT or any other transistor die.

In an embodiment the second substrate is an electrically conductive substrate, and the second structured metallization layer is arranged adjacent but isolated to the second substrate by a lowermost portion of the insulator substrate. Thereby, each section of the second structured metallization layer may be forming an EMI shielding capacitance together with the second substrate. EMI-wise these inner-shielding structures (namely the second metallization layer) are most efficient, if they are designed in a way, that the first section of the second metallization layer has the same coupling capacitance as the second section of the second metallization layer against the second substrate.

In particular, the second substrate may form a baseplate of the device and may be connected to ground potential and configured to be attached to a heatsink. A baseplate may be a thermally and/or electrically conductive plate being configured to be attached to a heatsink by, for example, a screw, a clip, diffusion soldering, soft soldering or sintering.

In an embodiment the first structured metallization layer comprises a third section which is galvanically isolated from both the first section and the second section of the first structured metallization layer, wherein the third section is configured to operate at an alternating potential. For example, in a half-bridge arrangement, a node in a coupling portion between a high side switch and a low side switch operates at an alternating potential, dependent on the switching state of the first and/or the second switch.

In an embodiment the insulator substrate comprises a routing layer, wherein the routing layer is arranged between the third structured metallization layer and the first metallization layer. The routing layer may be part of the stack of snubber capacitances but may also be a separate part.

The routing layer may also be referred to as a distribution layer. Advantageously, the routing layer may be the first layer seen from a topside in the layer stack of the insulator substrate. The routing layer may be a metallization layer configured to route incoming signals in a respective plane from one portion of the plane to another. For example, the routing layer may connect opposite parts of the second metallization layer to a respective potential. Thereby, an internal routing of electric potentials is possible.

In an embodiment the first section of the second structured metallization layer has a first surface area and the second section has a second surface area, which is basically equal to the first surface area, and/or wherein the first section and the second section are basically in the same plane. Thereby, the EMI shielding capacitances are basically equal, because they have basically the same footprint. For most effective EMI reduction, the first section of the second structured metallization layer may be connected to the positive potential of a DC-link voltage (first potential, DC+) and the second section of the second structured metallization layer may be connected to the negative potential of the DC-link voltage (second potential, DC-).

In an embodiment the second surface area is less than 1/0,95 of the first surface area and more than 1/1,05 of the first surface area. The surface area of a metallization layer may be regarded as the largest orthogonal projection of the area on a plane. By the above ratio of the first and the second surface area, the radiated EMI of a semiconductor device may be significantly reduced.

In an embodiment the intermeshing layer structures form one or more gate-source capacitors to reduce oscillations during switching of the one or more semiconductor dies. The intermeshing layer structures may also be used as gate-source capacitors, wherein in this embodiment the first potential to which the capacitor is coupled is a gate potential. The second potential to which the capacitor is coupled is the source potential. If more than one semiconductor switch is present, a separate capacitor inside the insulator substrate may be needed for each semiconductor switch. For example, if n semiconductor switches are present, n-1 gate-source capacitors may be needed to adapt the n-1 semiconductor switches to a first reference semiconductor switch. Both the gate potential and the source potential of each semiconductor switch is then electrically coupled to the respective capacitor inside the multilayer substrate.

To outweighed switching asymmetries, that is, differences in switching speed of respective semiconductor switches, the respective gate-source capacitances inside the insulator substrate may also be asymmetrical. In other words, the gate-source capacitances may be adapted to the switching speed of the respective semiconductor switches. Differences in switching speed, may for example result from different thermal conditions or asymmetries in the controlling circuit of the semiconductor switches.

In an embodiment the intermeshing layer structures form one or more external Miller capacitances. In this embodiment the respective capacitors inside the insulator substrate may also be connected to the gate potential and the collector potential of the respective switches. Thereby, each switch may be connected to a bespoke capacitor network to compensate for differences in switching speed. The difference in switching speed may thus be compensated by connecting the respective switch to a particular capacitance.

According to a second aspect of the present disclosure a semiconductor module arrangement is provided, the arrangement comprising an insulator substrate, a second conductive substrate attached to the insulator substrate, the insulator substrate comprising at least one EMI shielding layer, and an intermeshing layered structure configured to function as a stacked snubber capacitance.

### BRIEF DESCRIPTION OF THE DRAWINGS

Exemplary embodiments of the disclosure are described with reference to the following figures:

FIGS. 1a to 1c show different views of a schematic semiconductor device of the prior art.

FIG. 2a shows a schematic view of a semiconductor device according to the disclosure.

FIG. 2b shows a schematic view of a semiconductor device according to the disclosure.

FIG. 2c shows a schematic view of internal capacitances of an exemplary semiconductor device according to the disclosure.

FIG. 3 shows a possible construction sketch of a multi-layer ceramics substrate and its different planes.

FIG. 4 shows a cross section of a structured multi-layer ceramics substrate with an inner-shielding element and a DC-snubber capacitor-stack structure as shown in FIG. 3.

### DETAILED DESCRIPTION

In the following detailed description, reference is made to the accompanying drawings. The drawings show specific examples in which the disclosed subject matter may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connected pads and includes at least one semiconductor element with electrodes. The pads are electrically connected to the electrodes which includes that the pads are the electrodes and vice versa.

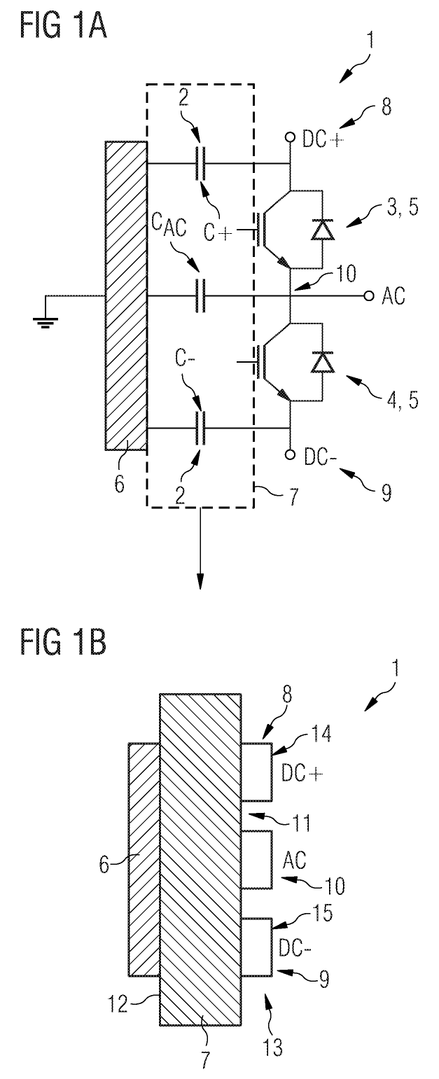

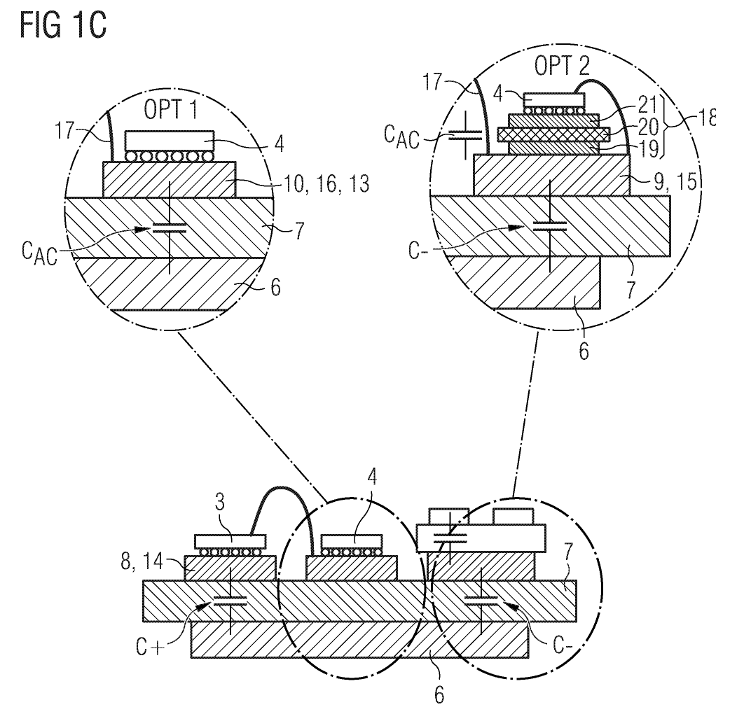

Referring to FIG. 1a (prior art), a semiconductor device 1 comprising an EMI shielding structure 2 is shown. The semiconductor device 1 comprises a first switch 3 and a second switch 4. The first switch 3 is a high side switch. The second switch 4 is a low side switch. The first switch 3 and the second switch 4 form a half-bridge arrangement 5.

The semiconductor device 1 further comprises a base plate 6, which may be connected to the ground potential. The semiconductor device 1 further comprises an insulator substrate 7. The EMI shielding structure 2 is contained in the insulator substrate 7. The insulator substrate 7 is connected to the baseplate 6, which may be a second substrate. The high side switch 3 is connected to a first potential 8 and coupled in series with the low side switch 4. The low side switch 4 may be coupled to a second potential 9. A portion in between the first switch 3 and the second switch 4 may comprise a node 10, which is configured to operate at the first or the second potential, that is, at an alternating potential AC depending on the switching state of the first and the second switch 3,4.

The EMI shielding structure 2 is buried in the insulator substrate 7. The EMI shielding structure 2 comprises a first EMI shielding capacitance C+ and a second EMI shielding capacitance C-. The first EMI shielding capacitance C+ is arranged between the base plate 6 and the first potential and for example connected to the positive potential of the DC-link voltage (DC+). The second EMI shielding capacitance C- is arranged between the base plate 6 and the second potential and for example connected to the negative potential of the DC-link voltage (DC-).

For effective EMI shielding the first EMI shielding capacitance C+ and the second EMI shielding capacitance C- are of about the same capacitance.

FIG. 1b (prior art) shows an outside view of the semiconductor device 1, wherein the baseplate 6 is arranged at the insulator substrate 7. The insulator substrate 7 comprises a first surface 11 and a second surface 12 opposite the first surface 11. The baseplate 6 is arranged at the second surface 12 of the insulator substrate 7. A first metallization layer 13, which is a structured layer, is arranged at the first surface 11 of the insulator substrate 7. The first metallization layer 13 comprises a first section 14 being configured to operate at the first potential 8. The first metallization layer 13 comprises a second section 15 being configured to operate at the second potential 9. Further, the first metallization layer comprises the node 10 configured to operate at an alternating potential.

The EMI shielding structure 2 is buried inside the insulator substrate 7, and hence not visible.

FIG. 1c shows a schematic overview over the capacitances contained in a semiconductor device 1 according to the prior art. FIG. 1c shows several optional embodiments, particularly related to a third EMI shielding capacitance C_{AC} arranged between the node 10 and the baseplate 6. As to the first EMI shielding capacitance and the second EMI shielding capacitance, the first metallization layer, that is the first section 14 of this first metallization layer 13 and the second section 15 of the first metallization layer form EMI shielding capacitances C+, C- together with the baseplate 6.

Option 1 shows the second semiconductor switch 4 arranged at a third section 16 of the first metallization layer 13. The third section 16 of the first metallization layer 13 forms the node 10, which is operating at an alternating potential AC. Node 10 is electrically coupled to a load electrode of the first switch 3 by means of a bond wire 17, for example. Further, node 10 is electrically coupled to a load electrode of the second switch 4. As per the first option a capacitor between the node 10 operating at alternating potential and the baseplate 6 is formed, wherein the insulator substrate 7 acts as the dielectric.

Option 2 shows a further possibility of implementing the third EMI shielding capacitance C_{AC}. A capacitor stack 18 is arranged atop the second section of the first metallization layer 15. The capacitor stack 18 comprises an electrically conductive lower layer 19, an insulator material 20 and an electrically conductive upper layer 21. The insulator material 20 is sandwiched between the electrically conductive lower layer 19 and the electrically conductive upper layer 21. The second semiconductor switch 4 is arranged atop the capacitor stack 18, that is bonded, soldered, sintered, or anyhow electrically connected to the electrically conductive upper layer 21.

The capacitor stack 18 is arranged between the second semiconductor switch 4 and the second section of the first metallization layer 15. The second semiconductor switch 4 is electrically connected to the electrically conductive upper layer 21 by one of its load electrodes. The electrically conductive upper layer 21 is connected by a bond wire 17 to a load electrode of the first semiconductor switch 3. Thereby electrically conductive upper layer 21 is configured to operate at the alternating potential. In this embodiment electrically conductive upper layer 21 takes the function of the node 10. Subsequently the capacitor stack 18 forms the third EMI shielding capacitance C_{AC.}

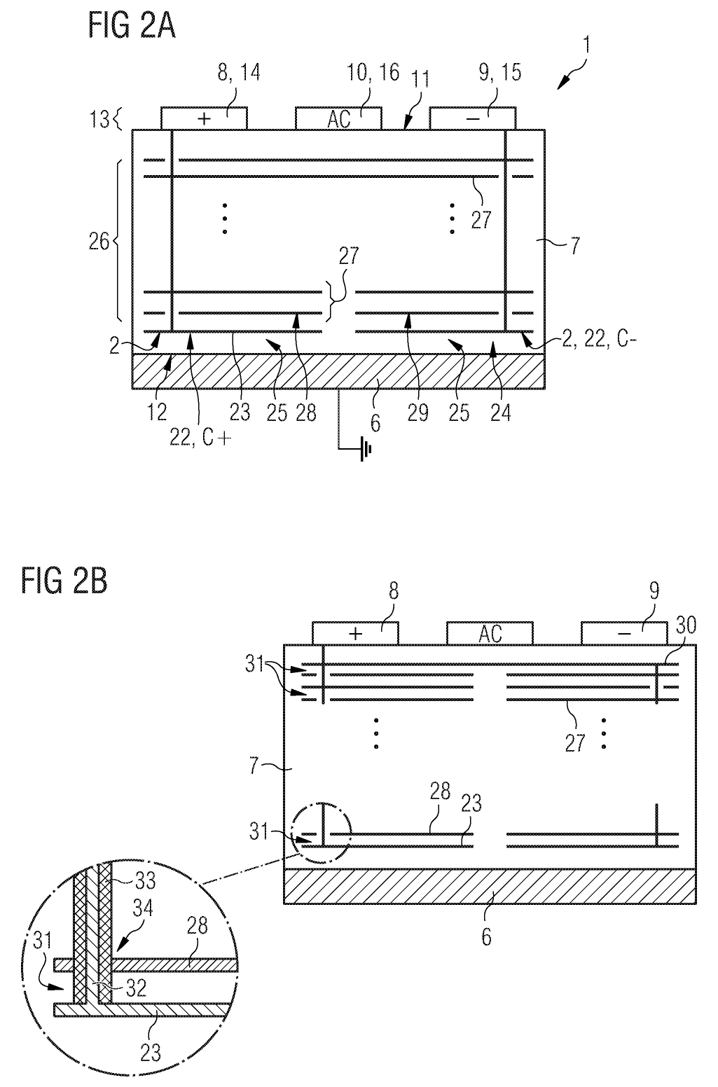

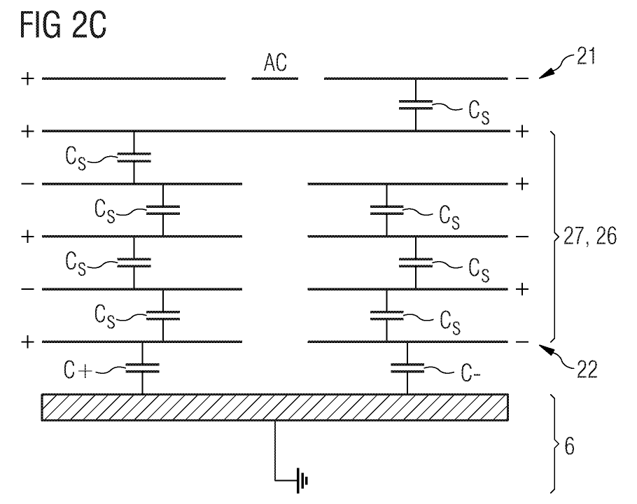

FIG. 2a shows a schematic view of a semiconductor device 1 according to the disclosure. The baseplate 6 is arranged at a lower side of the insulator substrate 7. The first metallization layer 13 is arranged at an upper side of the insulator substrate 7. The first metallization layer 13 is structured, that is, comprises a first section 14 configured to operate a first potential, a second section 15 configured to operate and a second potential and the third section 16 configured to operate at an alternating potential.

The first section 14 is configured to receive a first semiconductor die (not shown) and the second section 15 is configured to receive a second semiconductor die (not shown). Further, in another embodiment in which the semiconductor dies have a vertical structure, the first semiconductor die 3 may be mounted at the first section 14 and the second semiconductor die 5 may be mounted at the second section 15. The semiconductor dies may be mounted atop the respective section for example by soldering, sintering, glueing or diffusion soldering.

Inside the insulator substrate 7, the EMI shielding structure 2 is comprised. The insulator substrate 7 may be a ceramic substrate. The EMI shielding structure 2 is formed by a second structured metallization layer 22. The second structured metallization layer 22 comprises a first section 23 and a second section 24. The first section 23 of the second metallization layer and the second section 24 of the second metallization layer 22 are basically within the same plane and are basically of the same size. To elaborate, a surface area of the first section 23 equals a surface area of the second section 24 of the second structured metallization layer 22.

The baseplate 6 is a conductive substrate. Both sections 23,24 of the second structured metallization layer are arranged adjacent to the baseplate 6. However, both sections are each isolated from the baseplate 6 by a lowermost portion of the material 25 of the insulator substrate 7. Thus, shielding capacitances are formed by the second structured metallization layer 22 and the baseplate 6 with the material of the insulator substrate 7 being arranged in between, acting as the dielectric. The baseplate 6 is connected to the ground potential.

The insulator substrate 7 comprises a third structured metallization layer 26. The third structured metallization layer 26 comprises a plurality of routable layers. The plurality of routable layers forms the intermeshing layer structure 27 and/or a stacked layer structure inside the insulator substrate 7. The third structured metallization layer 26 comprises a first segment 28 coupled to the second potential 9. Further, the third structured metallization layer 26 comprises a second segment 29, which is electrically connected to the first potential 8.

The plurality of routable layers forms the intermeshing layer structure 27. The intermeshing layers of the intermeshing layer structure 27 form a capacitor stack. The intermeshing layers of the intermeshing layer structure 27 are alternatingly coupled to the first potential 8 and the second potential 9. The intermeshing layer structures 27 form multiple stacked snubber capacitances within the insulator substrate 7. Particularly, the first segment of the third structured metallization layer 28 forms a first snubber capacitance together with the first section of the second structured metallization layer 23, wherein the sections are again separated from one another by the material of the insulator substrate 7. In the same way, the second section 24 of the second structured metallization layer 22 forms the second snubber capacitance together with the second segment 29 of the third structured metallization layer 26.

In contrast to the first section 23 and the second section 24 of the second structured metallization layer 22, which are non-overlapping one another, layers of the intermeshing layer structure 27 are overlapping one another and are alternatingly coupled to the first and the second potential 8,9 and hence form a stacked plate capacitor structure within the insulator substrate 7.

The intermeshing layer structure 27 may comprise layers of different sizes. For example, as shown in the lower part of FIG. 2a, layers of the intermeshing layer structure 27 may have about an equal size as the first and second sections 23,24 of the second metallization layer 22. However, as shown in the upper part of FIG. 2a, the layers of the intermeshing layer structure 27 may extend across the whole lateral dimension of the insulator substrate 7.

FIG. 2b shows a schematic view of a semiconductor device according to the disclosure. The intermeshing layer structure 27 comprises a first upper layer, which may be a routing layer 30. The routing layer 30 is a redistribution layer, configured to distribute/root incoming potentials or signals to respective lower parts or layers of the intermeshing layer structure 27. Incoming potentials/or signals are distributed by routing layer 30 through a via structure 31 to lower layers of the intermeshing layer structure 27 inside the insulator substrate 7.

As various incoming potentials can be routed, by the redistribution layer to the intermeshing layer structure 27, also other potentials as DC + and DC - may be connected to the capacitor stack inside the insulator substrate 7.

For example, the first potential 8 may also be a gate potential, and the second potential 9 may also be a source potential. Hence, the intermeshing layer structure 27 may also form gate-source capacitors to reduce oscillations during switching of the one or more semiconductor dies 3,4.

As another example, the first potential 8 may be an drain potential and the second potential 9 may be a gate potential. The intermeshing layer structure 27 forms one or more external Miller capacitances in this configuration.

The extended view of FIG. 2b shows an exemplary embodiment of the via structure 31. As an example, the first section of the second structured metallization layer 23 is shown as a lowermost part being connected or contacted by the via structure 31. The first segment 28 of the third structured metallization layer is exemplarily shown as the layer through which an incoming signal, for example from the first potential 8, is transferred to the first section of the second metallization layer 23. To distribute the signal, a vertically conductive structure 32, which connects to the incoming potential/signal, is isolated by a vertical isolation structure 33. The vertical isolation structure 33 isolates the vertical conductive structure 32 from, for example, the first segment 28 of the intermeshing layer structure 27. To receive the vertical conductive structure 32 and the vertical isolation structure 33, each of the upper layers of the intermeshing layer structure 27, which are not supposed to be contacted by the incoming potential, comprise bores 34.

FIG. 2c shows a schematic view of internal capacitances of an exemplary semiconductor device according to the disclosure. First and second EMI shielding capacitances C+ /C- are formed between the second structured metallization layer 22 and the baseplate 6. The third structured metallization layer 26 forms a layer stack comprising a plurality of snubber capacitances C_{S}, which are in the present FIG. 2C indicated with a capacitor symbols. However, it is to be understood, that the capacitors/capacitance is formed by the stacking of layers with the material of the insulator substrate 7 is a dielectric in between. As can be seen, a series connection of a plurality of snubber capacitors is realized. As a means of visual reference, the polarity of the respective layers is indicated in FIG. 2c.

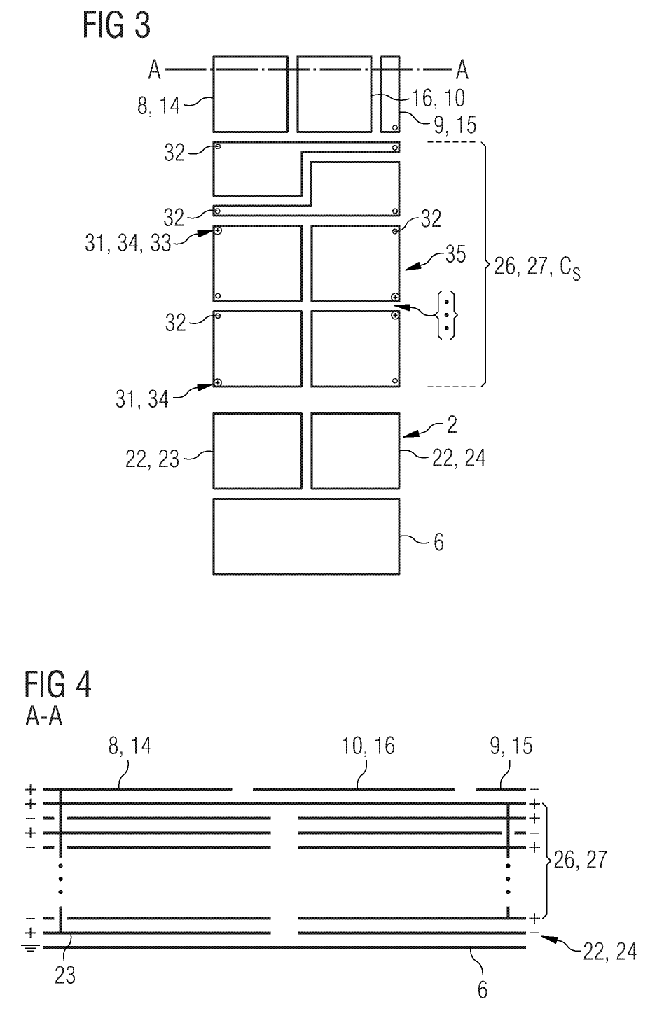

FIG. 3 shows a possible embodiment of a multi-layer ceramic substrate and its different planes and electrically conductive layers. The shown layer stack is a DC-snubber capacitor C_{S} in addition to the inner-shielding element 2, the EMI shielding structure 2. Each dot corresponds to an electrical connection in-between different layers by, e.g., the via structure 31. Each circle represents the vertical isolation structure 33 in the corresponding layer to the (enclosed) vertically conductive structure 32. For example, in a 2^{nd} inner layer 35, only the vertically conductive structure 32 in the upper corner on the right-hand side provides an electrical connection to the conductive layer. The vertically conductive structure 32 in the upper corner on the left-hand side is electrically insulated from the conductive layer of the 2^{nd} inner layer by vertical isolation structure 33 but provides an electrical connection to the conductive layer of a 3^{rd} inner layer 36.

FIG. 4 shows a cross section of a structured multi-layer ceramics substrate with an EMI shielding structure 2 and a DC-snubber capacitor-stack structure 26, 27 as shown in FIG. 3. The cut is done along the perpendicular plane A-A indicated in FIG. 3. To provide an inner shielding, the last layer, which is the second structured metallization layer 22, provides equally-sized elements 23,24. Again, as a visual aid, the polarity of the single layers of the layer stack is indicated at the respective layers of FIG. 4.

### LIST OF REFERENCE SIGNS

1 semiconductor device

2 EMI shielding structure

3 first switch

4 second switch

5 half bridge arrangement

6 baseplate, second substrate

7 insulator substrate

8 first potential

9 second potential

10 node

11 first surface of the insulator substrate

12 second surface of the insulator substrate

13 first metallization layer

14 first section of the first metallization layer

15 second section of the first metallization layer

16 third section of the first metallization layer

17 bond wire

18 capacitor stack

19 electrically conductive lower layer

20 insulator material

21 electrically conductive layer

22 second structured metallization layer

23 first section of the second metallization layer

24 second section of the second metallization layer

25 lowermost portion of material of the insulator substrate

26 third structured metallization layer

27 intermeshing layer structure

28 first segment of the third structured metallization layer

29 second segment of the third structured metallization layer

30 routing layer

31 via structure

32 vertical conductive structure

33 vertical isolation structure

34 bore

35 second inner layer

36 third inner layer

1. A semiconductor device, comprising:
an insulator substrate;
a second substrate arranged at a first surface of the insulator substrate; and
a first structured metallization layer arranged at a second surface of the insulator substrate opposite the first surface,
the first structured metallization layer comprising:
a first section configured to operate at a first potential; and
a second section configured to operate at a second potential;
the insulator substrate comprising:
a second structured metallization layer buried in the insulator substrate, configured for electromagnetic interference (EMI) shielding, arranged adjacent to the second substrate, comprising:
a first section coupled to the first potential; and
a second section coupled to the second potential, wherein the first section and the second section are non-overlapping; and
at least one routable third structured metallization layer, comprising:
a first segment coupled to the second potential; and
a second segment coupled to the first potential,
wherein the first section of the second structured metallization layer forms a first snubber capacitance with the first segment of the third structured metallization layer.

2. The semiconductor device of claim 1, wherein the second section of the second structured metallization layer forms a second snubber capacitance with the second segment of the third structured metallization layer.

3. The semiconductor device of claim 1, wherein the third structured metallization layer comprises a plurality of routable layers, the plurality of routable layers forming a plurality of intermeshing layer structures alternatingly coupled to the first potential and to the second potential, thereby forming multiple stacked snubber capacitances within the insulator substrate.

4. The semiconductor device of claim 3, wherein the plurality of intermeshing layer structures are embedded in the insulator substrate and arranged between the first structured metallization layer and the second structured metallization layer.

5. The semiconductor device of claim 3, wherein the plurality of intermeshing layer structures are alternatingly overlapping one another and form a plate capacitor structure within the insulator substrate.

6. The semiconductor device of claim 1, wherein the insulator substrate is one of a multilayer ceramic substrate, a multilayer PCB, or a multi-layer resin-based substrate.

7. The semiconductor device of claim 1, wherein the first section of the first structured metallization layer is configured to receive a first semiconductor die and the second section of the first structured metallization layer configured to receive a second semiconductor die.

8. The semiconductor device of claim 1, wherein the insulator substrate is a ceramic substrate and the second substrate is an electrically conductive substrate and wherein the second structured metallization layer is arranged adjacent but isolated to the second substrate by a lowermost portion of the ceramic substrate, each section of the second structured metallization forming an EMI shielding capacitance with the second substrate.

9. The semiconductor device of claim 1, wherein the second substrate forms a baseplate of the device and is connected to ground potential and configured to be attached to a heatsink.

10. The semiconductor device of claim 1, wherein the first structured metallization layer comprises a third section which is galvanically isolated from both the first section and the second section of the first structured metallization layer, wherein the third section is configured to operate at an alternating potential.

11. The semiconductor device of claim 1, wherein the insulator substrate comprises a routing layer, wherein the routing layer is arranged between the third structured metallization layer and the first metallization layer.

12. The semiconductor device of claim 1, wherein at least one of:
the first section of the second structured metallization layer has a first surface area and the second section has a second surface area which is basically equal to the first surface area; or
the first section and the second section are basically in the same plane.

13. The semiconductor device of claim 12, wherein the second surface area is less than 1/0,95 of the first surface area and more than 1/1,05 of the first surface area.

14. The semiconductor device of claim 3, wherein the plurality of intermeshing layer structures form one or more gate source-capacitors to reduce oscillations during switching of the one or more semiconductor dies.

15. The semiconductor device of claim 3, wherein the plurality of intermeshing layer structures form one or more external Miller capacitances.

16. A semiconductor module arrangement comprising:
an insulator substrate; and
a second conductive substrate attached to the insulator substrate,
the insulator substrate comprising:
at least one electromagnetic interference (EMI) shielding layer; and
an intermeshing layered structure configured to function as a stacked snubber capacitance.

17. A semiconductor device, comprising:
an insulator substrate;
a second substrate arranged at a first surface of the insulator substrate; and
a first structured metallization layer arranged at a second surface of the insulator substrate opposite the first surface,
the first structured metallization layer comprising:
a first section configured to operate at a first potential; and
a second section configured to operate at a second potential;
the insulator substrate comprising:
a second structured metallization layer arranged adjacent to the second substrate, comprising:
a first section coupled to the first potential; and
a second section coupled to the second potential; and
at least one routable third structured metallization layer, comprising:
a first segment coupled to the second potential; and
a second segment coupled to the first potential,
wherein the first section of the second structured metallization layer forms a first snubber capacitance with the first segment of the third structured metallization layer.

18. The semiconductor device of claim 17, wherein the second section of the second structured metallization layer forms a second snubber capacitance with the second segment of the third structured metallization layer.

19. The semiconductor device of claim 17, wherein the third structured metallization layer comprises a plurality of routable layers, the plurality of routable layers forming a plurality of intermeshing layer structures.

20. The semiconductor device of claim 19, wherein the plurality of intermeshing layer structures are embedded in the insulator substrate and arranged between the first structured metallization layer and the second structured metallization layer.
